(19) United States
(12) Patent Application Publication
(10) Pub. No.: US 2010/0112293 A1
(43) Pub. Date: May 6, 2010

(54) DEVICE HOUSING AND METHOD FOR MANUFACTURING THE SAME

(75) Inventors: HONG-BO LI, Shenzhen City (CN); GANG HUANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/604,920

(22) Filed: Oct. 23, 2009

(30) Foreign Application Priority Data
Nov. 6, 2008 (CN) 200810305410.1

(51) Int. Cl. B32B 3/00; C23C 14/24; B44C 1/22

(52) U.S. Cl. 428/161; 427/248.1; 216/37

(57) ABSTRACT

A device housing and a method of fabricating the device housing are provided. The device housing includes a base housing, a bottom coating, a vacuum evaporation coating, an intermediate coating, a fill coating and a top coating. The base housing is recessed to define a plurality of textured portions. The bottom coating is formed on the base housing and covers the textured portions. The vacuum evaporation coating is formed on the bottom coating. The intermediate coating is formed on the vacuum evaporation coating and has recessed sections corresponding to the textured portions. The fill coating is formed on the intermediate coating and fills the recessed sections. The top coating covers the intermediate coating and the fill coating.

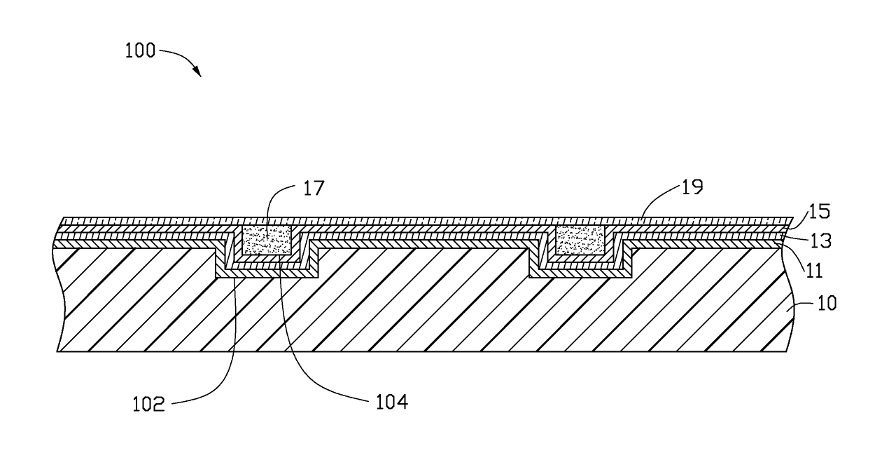

### BACKGROUND

1. Technical Field

The present disclosure relates to a device housing and a method for manufacturing the device housing.

2. Description of Related Art

Electronic devices such as mobile phones usually fabricate their housings with decorative sprayed paints. The painted exterior surface of the housing is then printed with patterns layers. However, the printed pattern layer may be boring and cannot present a graceful metallic appearance. Further, due to exposure to the outside, the pattern layers tend to be worn or eroded, which may degrade the aesthetic appearance of the housing.

Therefore, there is room for improvement within the art.

### BRIEF DESCRIPTION OF THE DRAWING

Many aspects of the new device housing and a method for manufacturing the device housing can be better understood with reference to the following drawing. The components in the drawing are not necessarily drawn to scale, the emphasis instead being placed upon clearly illustrating the principles of the new device housing and a method for manufacturing the device housing.

The FIGURE is a cross section of an exemplary device housing as disclosed.

### DETAILED DESCRIPTION

The FIGURE shows an exemplary device housing 100 including a base housing 10, a bottom coating 11 directly formed on the base housing 10, a vacuum evaporation coating 13 directly formed on the bottom coating 11, an intermediate coating 15 directly formed on the vacuum evaporation coating 13, a fill coating 17 directly formed on the intermediate coating 15, and a top coating 19 exposed to the outside. The top coating 19 covers portions of the intermediate coating 15 and the fill coating 17.

The base housing 10 can be a plastic housing molded of one or more plastics selected from a group consisting of polyethylene (PE), polyamide (PA), polycarbonate (PC), acrylonitrile-butadiene-styrene (ABS), polymethyl methacrylate (PMMA) and polyethylene terephthalate (PET). Alternatively, the base housing 10 can be a metallic housing. The base housing 10 has a plurality of recessed textured portions 102. The bottom of the textured portions 102 has a predetermined textured pattern formed by a process of molding or chemically etching.

The bottom coating 11 is an ultraviolet (UV) coating. The UV coating may contain a preformed polymer of acrylic polyurethane and a UV initiator.

The vacuum evaporation coating 13 is vacuum evaporated on the bottom coating 11 by using a target made of a metallic material selected from a group consisting of indium (In), tin (Sn), aluminum (Al), stainless steel, chromium (Cr), silicon (Si), and silicon dioxide (SiO2). The bottom coating 11 bonds well with the vacuum evaporation coating 13, and further enhances the glossy appearance of the vacuum evaporation coating 13.

The intermediate coating 15 allows at least some light transmittal therethrough and is made of a UV paint, a polyurethane paint or an unsaturated polyester paint. The intermediate coating 15 bonds well with the vacuum evaporation coating 13.

The bottom coating 11, the vacuum evaporation coating 13 and the intermediate coating 15 are stacked on the base housing 10. Due to the textured portions 102, the stacked base housing 10 have corresponding recessed sections 104. The fill coating 17 allows at least some light transmittal therethrough and is made of ink or a colloidal solution. The fill coating 17 fills in the recessed sections 104 to make them coplanar with the intermediate coating 15. The fill coating 17 can have a different color from the intermediate coating 15, enabling the pattern on the bottom of the textured portions 102 to have more contrast with each other.

The top coating 19 is transparent and made of a UV paint, a polyurethane paint or an unsaturated polyester paint. The top coating 17 has a high rigidity to provide a good protection for the intermediate coating 15 and the fill coating 17 from, for example, wear and tear.

A method for manufacturing the device housing 100 as described may include the following steps.

The base housing 10 is provided with the plurality of textured portions 102 for example by molding. A predetermined pattern is molded or chemically etched on the bottom of the textured portions 102. The bottom coating 11 is sprayed onto the exterior surface of the base housing 10.

The vacuum evaporation coating 13 is vacuum evaporated onto the exterior surface of the bottom coating 11. During this step, an opaque cover housing with hollowed portions covers the bottom coating 11 of the base housing 10. The hollowed portions correspond to the vacuum evaporation coating 13 in shape and size. The cover housing and the base housing 10 are vacuum evaporated to form the vacuum evaporation coating 13 through the hollowed portions on the bottom coating 11. After completing of the vacuum evaporation, the cover housing is removed.

The intermediate coating 15 is sprayed on the vacuum evaporation coating 13. In this case, the preformed base housing 10 has the recessed sections 104 corresponding to the textured portions 102. The fill coating 17 is filled into the recessed sections 104. The middle coating 15 is sprayed on the vacuum evaporation coating 13. The top coating 19 is sprayed on and covers the intermediate coating 15 and the fill coating 17.

It is to be understood, however, that even through numerous characteristics and advantages of exemplary embodiments have been set forth in the foregoing description, together with details of the structure and function of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A device housing, comprising:
a base housing comprising a plurality of recessed textured portions;
a bottom coating formed on the base housing and covering the textured portions;
a vacuum evaporation coating formed on the bottom coating;
an intermediate coating formed on the vacuum evaporation coating, the intermediate coating comprising recessed sections respectively corresponding to the recessed textured portions;
a fill coating formed on the intermediate coating and filling the recessed sections; and
a top coating covering the intermediate coating and the fill coating.

2. The device housing as claimed in claim 1, wherein the fill coating allows at least some light transmittal therethrough and is made of ink or a colloidal solution.

3. The device housing as claimed in claim 2, wherein the fill coating is coplanar with the intermediate coating.

4. The device housing as claimed in claim 2, wherein the fill coating has a different color from the intermediate coating.

5. The device housing as claimed in claim 1, wherein the top coating is transparent and made of a UV paint, a polyurethane paint or an unsaturated polyester paint.

6. The device housing as claimed in claim 1, wherein the intermediate coating allows at least some light transmittal therethrough and is made of a UV paint, a polyurethane paint or an unsaturated polyester paint.

7. The device housing as claimed in claim 1, wherein the bottom coating is an ultraviolet coating.

8. The device housing as claimed in claim 1, wherein the base housing is made of one or more plastics selected from a group consisting of made of a plastic material selected from a group consisting of Polyethylene (PE), polyamide (PA), polycarbonate (PC), acrylonitrile-butadiene-styrene (ABS), polymethyl methacrylate (PMMA) and polyethylene terephthalate (PET).

9. The device housing as claimed in claim 1, wherein the base housing is a metal housing.

10. A manufacturing method for device housing, comprising:
providing a base housing having a plurality of recessed textured portions;
forming a bottom coating on the surface of the base housing, the bottom coating covering the textured portions;
vacuum evaporating a vacuum evaporation coating on the surface of the bottom coating;
forming an intermediate coating, allowing at least some light transmittal therethrough, on the surface of the pattern layer, forming a plurality of recessed sections corresponding to the textured portions in the intermediate coating; and
forming fill coating, having a degree of transparency, on the intermediate coating by filling the fill coating into the recessed sections
forming a transparent top coating on the surface of the middle coating; and
forming a top coating covering the intermediate coating and the fill coating.

11. The manufacturing method as claimed in claim 10, wherein the bottom coating is sprayed a UV paint.

12. The manufacturing method as claimed in claim 10, wherein a target for the process of vacuum evaporation is a metallic material selected from a group consisting of indium (In), tin (Sn), aluminum (Al), stainless steel, chromium (Cr), silicon (Si), and silicon dioxide (SiO₂).

13. The manufacturing method as claimed in claim 10, wherein the intermediate coating is sprayed a UV paint, a polyurethane paint or an unsaturated polyester paint.

14. The manufacturing method as claimed in claim 10, wherein the top coating is spayed a UV paint, a polyurethane paint or an unsaturated polyester paint.

15. The manufacturing method as claimed in claim 10, wherein the textured portions are processed by molding or chemically etching.

16. The manufacturing method as claimed in claim 10, wherein the fill coating has a degree of transparent and is made of ink or a colloidal solution.

17. The manufacturing method as claimed in claim 16, wherein the fill coating is coplanar with the intermediate coating.

18. The manufacturing method as claimed in claim 16, wherein the fill coating has a different color from the intermediate coating.
